(19) United States
(12) Patent Application Publication
(10) Pub. No.: US 2010/0126273 A1
(43) Pub. Date: May 27, 2010

(54) FLEXIBLE IMPACT SENSORS AND METHODS OF MAKING SAME

(75) Inventors: Hee Chuan Lim, Houston, TX (US); Yew Fong Hor, Houston, TX (US)

Correspondence Address: GIBSON & DERNIER LLP, 900 ROUTE 9 NORTH, SUITE 504, WOODBRIDGE, NJ, 07095, US

(73) Assignee: NEW JERSEY INSTITUTE OF TECHNOLOGY, Newark, NJ (US)

(21) Appl. No.: 12/624,898

(22) Filed: Nov. 24, 2009

Related U.S. Application Data
(60) Provisional application No. 61/117,764, filed on Nov. 25, 2008.

(51) Int. Cl. G01P 15/00; C23C 14/34

(52) U.S. Cl. 73/514.16; 204/192.21

(57) ABSTRACT

Flexible impact sensors are provided which are constructed of flexible polyimide substrate, electrodes and a pressure-sensitive electrically conductive polymer composite layer having conductive nanoparticles. Dual-purpose impact and temperature sensors are also described. Methods of making flexible impact sensors are disclosed.

### CROSS-REFERENCE TO RELATED APPLICATIONS

This application claims the benefit of U.S. Provisional Patent Application No. 61/117,764, filed Nov. 25, 2008, the entirety of which is incorporated herein by reference.

### FIELD OF THE INVENTION

In general, the invention relates to impact sensors. Specifically, the invention relates to flexible impact sensors and methods of making same.

### BACKGROUND OF THE INVENTION

Transported apparatus or materials regularly experience mechanical shocks in the course of their functional life cycle. The subjected physical shocks, however brief, from a fraction of a millisecond to several milliseconds in duration, are frequently severe, damaging and cannot be overlooked. If the shock recurs many times, such as the shock recorded on air-dropped munitions and equipment or the landing gear of an aircraft, the fatigue damage accumulated in the structural elements can lead to fracture. The shock induces transitory dynamic stress in structures. These stresses are a function of the characteristic of the shock, i.e., amplitude, duration, and shape, and the dynamic properties of the structure, i.e., resonant frequencies, Q factors and the like.

Researchers have investigated cost-efficient and less complex methods of producing rugged transducers to track force impulses or momentum variations. In addition to the popular but expensive MEMS-based accelerometer approach (V. Biefeld et al, Laterally driven accelerometer fabricated in single crystalline silicon, Sensors and Actuators A, Vol. 82, Issue 1, 2000, pp. 149-154; H. Xie et al., CMOS z-axis capacitive accelerometer with comb-finger sensing, IEEE Micro Electro Mech. Syst. (MEMS), 2000, pp. 496-501), thick film (K. Arshak et al., PVB, PVAc and PS pressure sensors with interdigitated electrodes, Sensors and Actuators A, Vol. 132, 2006, pp. 199-206) and drop coating (J. Chlistunoff et al., Electrochemistry of fullerene films, Thin Solid Films, Vol. 257, 1995, pp. 166-184), alternative technologies using highly conductive filler, i.e., carbon black and surfactant, have been attempted. Other conductive polymer based approaches (L. Flandin et al., Electrically conductive polymer nano-composites as deformation sensors, Compos. Sci. Technol., Vol. 61, 2001, pp. 895-901; J. N. et al., Effect of mechanical deformations on structurization and electric conductivity electric conducting polymer composites, J. Appl. Polym. Sci., Vol. 74, 1999, pp. 601-621) and the oscillating cantilever based approach for shock and vibration sensor/transducer have been investigated. See, X. Fang et al., Analysis of micro-machined cantilevers in transverse shock, Chinese J. of Semiconductors, Vol. 26, Issue 2, 2005, pp. 379-384; Q. M. Li et al., Pressure-impulse diagram for blast loads based on dimensional analysis and single degree-of-freedom model, J. of Eng. Mech., Vol. 128, Issue 1, 2002, pp. 87-92; A. A. Van Netten et al., A study of blast loading on cantilevers, Shock Waves, Vol. 7, Issue 3, 1997, pp. 175-190. Each of these devices suffers from some drawback such as costliness, complexity and/or lack of robustness. Thus, there is a need for a cost-effective, robust but simple impact sensor which exhibits good resistivity characteristics with external applied force.

### SUMMARY OF THE INVENTION

In accordance with one embodiment the present invention includes an impact sensor constructed with one or more pressure sensitive polymer layers and conductive electrodes disposed on a flexible membrane substrate. The described devices are cost-effective, robust and relatively simple to manufacture and use.

In one embodiment the impact sensor is a flexible piezoresistive-based impact sensor constructed of flexible polyimide substrate, electrodes and a pressure-sensitive electrically conductive polymer composite layer having conductive nanoparticles.

In another embodiment the impact sensor is reversible and includes a pressure-sensitive polymer layer having a cross-linked synthetic polymer matrix and highly conductive nanoparticles.

In another embodiment the highly conductive nanoparticles may be selected from silver, gold, copper, a solution such as Indium Tin Oxide (ITO) and conductive polymer Poly(3,4-ethylenedioxythiophene) poly(styrenesulfonate) (PEDOT:PSS).

In a further embodiment the present invention provides maximum bonding between conductive nanoparticles, the polymer and the substrate for stable transducer characteristics intended for harsh environments, but without strong adhesive force between the conductive electrodes/polymer interface.

In accordance with at least one embodiment an impact sensor is provided having highly conductive electrode pairs such as but not limited to Al electrodes.

In one embodiment the polymer layer may be coated or encapsulated with a further layer such as a passivative layer of silicon nitride (SiNx). For example, a SiNx encapsulation layer may protect the entire sensor from harsh environmental conditions, such as moisture, —OH radicals, foreign particles, etc. This layer can also function as a strong adhesive layer for subsequent deposition of the conductive electrode layer, disposed on top of the flexible substrate, to reduce and/or eliminate electrode delamination and prolong sensor life by resistance to rough handling or bending.

In one embodiment a passivative layer of SINx is approximately 300-350 nm thick and may be deposited via Plasma Enhanced Chemical Vapor Deposition (PECVD).

In still a further embodiment devices of various impulse threshold or sensitivity are provided by varying the polymer thickness.

The electrical resistance changes of the conductive polymer strongly depend on the external applied stress. Upon any impacts the resistance of the active conductive polymer elements will change from >500 MΩ to as low as 0.1Ω if the pressure or force surpasses the designed/preset actuation pressure.

Due to the robust nature of the conductive polymer, the described devices can be used in harsh environments such as marine (salt water), outdoor (acid rain), rapidly fluctuating relative humidity and thermal shock conditions. The sensors are of particular use in apparatus such as aircraft, automobiles, construction equipment and weapon systems.

In a further embodiment a method of making a flexible piezoresistive-based impact sensor includes providing a flexible polyimide substrate, disposing an electrode on the substrate, and disposing on the electrodes a pressure-sensitive electrically conductive polymer composite layer having conductive nanoparticles.

In a further embodiment a method of making an impact sensor includes disposing an electrode on a substrate by sputtering a highly conductive material thereon.

In still a further embodiment a combined temperature monitor and impact sensor is disclosed including at least one conductive polymer layer, a flexible substrate, and at least one electrode pair disposed between the at least one conductive polymer layer and the flexible substrate.

### BRIEF DESCRIPTION OF THE DRAWINGS

So that those having ordinary skill in the art will have a better understanding of how to make and use the disclosed systems and methods, reference is made to the accompanying figures wherein:

FIG. 1 is a schematic depiction of an impact sensor in accordance with at least one embodiment of the present invention;

FIG. 2 is a graphical depiction of electrical resistance R (Ohm) decaying exponentially with external applied load (grams) in accordance with at least one aspect of the present invention. The sample thickness is 0.5 mm with contact area of 1 cm²;

FIG. 3 is a graphical depiction of electrical resistance changes over time held under constant applied load of 1000 g/cm² or 14.22 psi in accordance with at least one aspect of the present invention. The sample thickness is 0.5 mm with contact area of 1 cm²; and

FIG. 4 is a graphical depiction of electrical resistance (R) changes over time held under constant applied load of 1000 g/cm² as a function of temperature (T) in accordance with at least one aspect of the present invention. The sample thickness is 0.5 mm with contact area of 1 cm².

### DETAILED DESCRIPTION OF THE INVENTION

The following is a detailed description of the invention provided to aid those skilled in the art in practicing the present invention. Those of ordinary skill in the art may make modifications and variations in the embodiments described herein without departing from the spirit or scope of the present invention. Unless otherwise defined, all technical and scientific terms used herein have the same meaning as commonly understood by one of ordinary skill in the art to which this invention belongs. The terminology used in the description of the invention herein is for describing particular embodiments only and is not intended to be limiting of the invention. All publications, patent applications, patents, and other references mentioned herein are expressly incorporated by reference in their entirety.

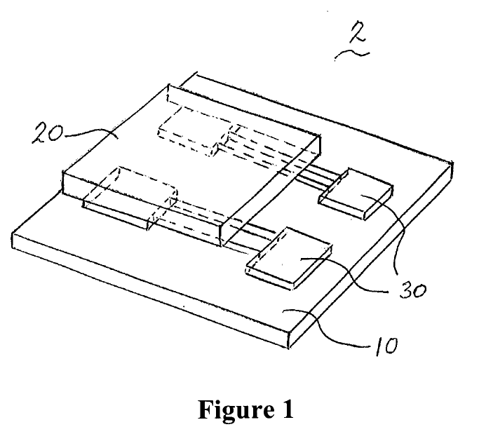

Now referring to FIG. 1, an exemplary impact sensor 2 includes substrate 10, polymer layer 20 and electrodes 30. Electrodes 30 are disposed on a surface of substrate 10. polymer layer 20 is disposed on a portion of electrodes 30.

Substrate 10 is preferably flexible and formed of a sturdy material. Suitable materials include but are not limited to polyimide films such as Kapton® E polyimide film available from DuPont. Polyimide films generally have high temperature stability and processing tolerance (mechanical/shear modulus). See, H. C. Lim, et al., Flexible membrane pressure sensor, Sensors and Actuators A: Physical, Vol. 119, Issue 2, 2005, pp. 332-335, incorporated by reference herein in its entirety. Substrate 10 is sized depending on a particular application. Substrate 10 is preferably thin. For example, a substrate 10 may be about 20 microns to about 300 microns in thickness, preferably about 52 microns thick. The dimensions of the substrate 10 may be about 0.7 cm to about 2.54 cm in length, 0.7 cm to about 2.54 cm in width, preferably about 1.0 cm wide and about 1.0 cm long.

Polymer layer 20 is preferably flexible and lightweight. In one embodiment polymer layer 20 may be composed of one or more polymer film layers. In a preferred embodiment the polymer layer 20 is formed of shock/impact sensitive conductive polymer. An example of such a conductive polymer is highly elastic Zoflex FL75.1 liquid conductive rubber commercially available from Xilor, Inc., with highly conductive nano-sized silver ink commercially available from Nanomas Tech of Endicott, N.Y. In one embodiment, the polymer layer 20 may be coated or encapsulated with a layer of SiNx.

Polymer layer 20 is sized depending on a particular application. Polymer layer 20 is preferably thin. For example, a polymer layer 20 may be about 50 nm to about 500 nm in thickness, preferably about 300 nm to 350 nm thick. The polymer layer may have a length of about 5.0 mm to about 1.5 cm, and a width of about 5.0 mm to about 1.0 cm. The polymer layer 20 may encompass and encapsulate the entire sensor layout.

Electrodes 30 may be any suitable electrode device known to those having skill in the art. The electrodes 30 are preferably highly conductive. In one embodiment pairs of highly conductive Al electrodes are employed. The electrodes 30 may be disposed on the substrate 10 by any suitable means such as by sputtering. The electrodes 30 may be patterned using standard photolithography and chemical etching. Preferably the pairs of electrodes 30 are spaced according to modeled pair spacing guidelines. The spacing may be modeled using any suitable modeling software such as but not limited to the electrical conductive model on Comsols Multiphysics software version 3.3a. The size of electrodes 30 is dependent on the application. Electrode 30 sizes may be in the range of from about 0.7 cm to about 2.54 cm in length to about 0.2 cm to about 0.5 cm in width, preferably about 1.0 cm long and 0.3 cm wide.

As assembled, the entire impact sensor 2 may be any suitable dimension depending on the application. In a preferred embodiment, the sensor 2 has a very low profile with a thickness preferably less than about 0.5 mm.

According to the popular model derived by X. W. Zhang et al., Time dependence of piezoresistance for the conductor-filler polymer composites, J. Polym. Sci. B, Vol. 38, 2000, pp. 2739-2749, the total changes of electrical resistance R of the polymer composite is calculated from the following relation:

$$R = ( \frac{L}{N} ) ( \frac{8 π hs}{3 {a}^{2} {γe}^{2}} ) {e}^{γ s} , \qquad ( 1 )$$

where, L is the number of particles forming the single conductive network path, N is the number of the numbers of the conductive paths, h is the Planck's constant, s is the minimum spacing between the conductive particles, α² is the effective cross-sectional area, where the tunneling occurs, and e is the electron charge. γ is given by:

$$γ = \frac{4 {π ( 2 m φ )}^{1 / 2}}{h} , \qquad ( 2 )$$

where, m is the electron mass and φ is the potential barrier between adjacent particles.

When a shock or impact is incident to the polymer shock transducer, the resistance will be altered because of the change of the conductive particle separation. Let the particle separation change from so to s with the applied forces, corresponding to the changes in resistance Rₒ to R.

The relative resistance is given by:

$$\frac{R}{{R}_{o}} = ( \frac{s}{{s}_{o}} ) {e}^{γ ( s - {s}_{o} )} \qquad ( 3 )$$

with Rₒ and sₒ is the initial resistance and initial particle separation respectively. The Rₒ of the conductive polymer is typically in the range of 30 MΩ.

For the case of the polymer composites under compressive strain, the sensor under compression particle's separation, s, is shorter that the initial uncompressed particle's separation, so (i.e. |s|<<|so|). Hence, the resistance under compression is lower than the initial uncompressed resistance as observed in the experimental results. It is also noted that the relationship observed (resistance vs. pressure) has the exponential function behavior similar to the theoretically derived model (negative exponential trends as exponential variables, s−so is less than zero) and its coefficient's amplitude can never have negative values.

If a large enough stress or impact is applied that surpasses the polymer elasticity limit (shock limit), the sensor would have the characteristics of a “shorted” conductor as the particle separation is approximately equal to zero. This is recognizable and proved by letting the particle separation s equal to zero in the above Equation 3, and therefore R is practically equal to zero.

### Experiments

An impact sensor was fabricated having the design as shown in FIG. 1. The sensor in this embodiment was designed to take advantage of the flexibility and light weight of a polymer membrane. In addition, this exemplary sensor has a very low profile with a max thickness of 0.59 mm. Kapton E was selected as the substrate in this embodiment of the invention due to its thermal (high temperature stability) and processing tolerance (mechanical/shear modulus) properties. The substrate was prepared and cut into 4″ in diameter circular shapes followed by the standard 3× pre-clean cycles of 1 hr iterations of boiling with M-clean cleaning agent, ultrasonic treatment, and rinsing. After the regular cleaning procedure for the flexible Kapton E membranes, an O₂ plasma of 11 W power via a Plasma Enhanced Chemical Vapor Deposition (PECVD) system was applied to modify the polyimide Kapton E surface roughness for better adhesion of deposited layers.

A layer of highly conductive Al electrodes was next sputtered using a Varian 3125 DC S-gun metal sputterer according to the specifically modeled pair spacing. The pairs of electrodes were next patterned using standard photolithography techniques and wet chemical etched with Aluminum etch bath. The electrode sizes were measured to be 0.7 mm L with 0.3 mm W with different electrodes spacing between them. The spacing was modeled using the electrical conductive model on Comsols Multiphysics software version 3.3a.

The shock/impact sensitive conductive polymer used for the impact sensor studies was made of highly elastic Zoflex FL75.1 liquid conductive rubber and highly conductive Nanomastech nano-sized silver ink. See, Roldughin et al., Percolation properties of metal-filled films, structure and mechanisms of conductivity, Progr. Org, Coat., Vol. 39, 2000, pp. 81-100, incorporated herein by reference in its entirety. The active elements of the composite had a “Shore A” hardness of 78 but were highly conductive due to the proper mixing rate and 1:6.63 chemical ratios. The specific gravity of the composite was 2.1. For the measurements of the change of electrical resistivity as a function of applied load or pressure, several 3-D rectangular structures were made and prepared via stencil printing technique.

Polymer samples of the dimension of 0.5 mm H×6.84 mm W×5.5 mm L for 2.6 mm electrode spacing and 0.5 mm H×6.37 mm W×12.91 mm L for the 4.8 mm electrode spacing were prepared. The polymer was cured at 25° C. or 77° F. for approximately 10 hours. Post-curing and annealing steps were also performed at 50° C. for approximately 3 hours to reduce bulking and removal of contaminants such as amines, sulfur, and soaps.

The impact sensor device was next wired with pure indium solder at 800° F. via a tiny soldering iron tip and interfaced with a computer controlled digital multimeter (Protek 506 DMM digital multimeter). The electrical resistance of the device was measured using a multimeter and interfaced with a LabVIEW program written for averaging, error minimization and storage. A shock and vibration test bench was built to test the fabricated impact transducer in an exemplary embodiment. The vibration test bench was equipped with a load cell. The shock and vibration bench was capable of generating Sine or Sawtooth waveforms. The frequency was varied with the use of the HP 33120A waveform generator. The shock and vibration test bench was calibrated with an INTERFACE SMT-1-10N load cell. The maximum force that could be excited and fed back was 100N (overload) with a sensitivity of +/−0.0005N. The load cell was interfaced to the PC data acquisition via a LabVIEW program. The LabVIEW program was capable of monitoring both the sensor response output and table movement or load.

A 1000 gram load was applied to the conductive polymer shock sensor of this exemplary embodiment inside a sealed environmental chamber for thermal cycling experiments. The testing conditions included temperature ranges from room temperature of about 25° C. to 80° C. (176° F.) at 35% constant relative humidity.

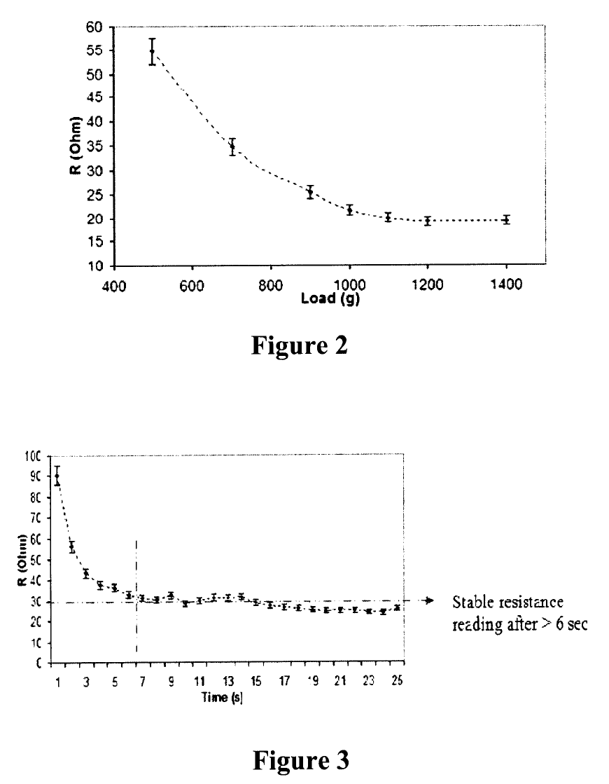

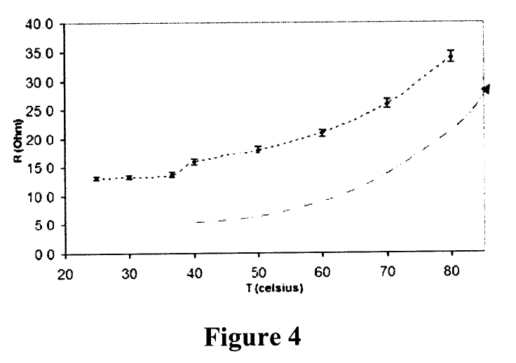

Now referring to FIG. 2, the measured data was plotted. The electrical resistance was measured within 1 second after the application of each load. The electrical resistance of the samples changed by 6 orders of magnitude from the nominal 30 MOhm range to approximately 20 Ohm and subsequently returned to its initial value after the load was removed within/in less than 800 msec. It is believed the reversibility and the large changes in electrical resistance under mechanical deformation by the loads were due to the higher mobility of the micro particles and the strong adhesion of the silver particles to the elastic polymer matrix. See, Knite et al., Electrical and elastic properties of conductive polymeric nanocomposites on macro- and nano-scales, Mater. Sci. Eng. C, Vol. 19, 2002, pp. 15-19, incorporated by reference herein in its entirety. For conductive polymer transducers of 0.5 mm thickness, the resistance output decays exponentially with external applied loads. When a shock or impact is incident to the sensor, the resistance is altered because of the change of the conductive particle separation. The conductive polymer-based impact sensors described herein exhibit fast resistivity transformation characteristics with external applied force/pressure, at least in part due to the formations of the conductive structure of the electro-conductive nano-size channel network.

Next, the time dependence of the conductive polymer transducer electrical resistance was investigated. A constant load of 1000 g/cm² or 14.22 psi was used in the testing of this embodiment. The response is as shown in FIG. 3. The conductive polymer electrical resistance was measured for >5 min at a time but only the first 25 sec of activity was plotted since duration longer than the first 25 sec is a flat DC response. The sample cross sectional area was 1 cm² with a thickness of 0.5 mm. It was observed that the resistance response of the impact sensor had a transient decay that mimicked an un-normalized negative exponential function. The response was measured and averaged at a rate of 60 counts/sec using a Protek DMM 506 digital multimeter. The resistance stabilized after approximately 6 sec after the loading. Without being held to any one theory, it is believed the delay in response might have been due to the sponginess or “Shore A” hardness mixture ratio (γ, reaction constant) coupled with the thickness of the polymer used in this particular experiment.

Next, the output (i.e., resistance) of the conductive polymer-based impact sensor was measured as a function of temperature after the resistance had stabilized from the typical loading time decay. This duration was inferred from the conductive polymer decay response in FIG. 3. The average wait time was approximately 8 sec. During this period, the chamber temperature was well stabilized so that any transient temperature effects were minimized. Several sets of readings were measured before increasing the temperature to the next level. The electrical resistance as a function of temperature was as plotted in FIG. 2. A constant load of 1000 grams was used for this experiment. The conductive polymer-based impact sensor exhibited a very weak semimetals-like temperature dependence of resistance. The sensor exhibited the electrical resistivity dependence as a function of temperature much like a weak semiconductor with a negative indirect energy band gap. Hence, it was surprisingly found that the sensor can also serve as an elevated temperature monitor or fuse inside an enclosed body. Hysteresis effects were not measured or observed as cooling rates were not satisfactorily controllable with the environmental chamber employed.

The conductive polymer-based impact sensor exhibited successful test results under standard laboratory conditions. The governing state equation of the conductive-polymer based transducer is as derived in equation (3). It is accurate in terms of both the sensor trends and functionality (negative exponential inclination). The resistance of the sensor is also dependent on the surrounding thermal effects. This is an added advantage besides monitoring impact in that it can also double as an elevated thermal indicator, as most ammunitions are also thermal-sensitive.

Although the systems and methods of the present disclosure have been described with reference to exemplary embodiments thereof, the present disclosure is not limited thereby. Indeed, the exemplary embodiments are implementations of the disclosed systems and methods are provided for illustrative and non-limitative purposes. Changes, modifications, enhancements and/or refinements to the disclosed systems and methods may be made without departing from the spirit or scope of the present disclosure. Accordingly, such changes, modifications, enhancements and/or refinements are encompassed within the scope of the present invention.

All references cited herein are incorporated by reference herein in their entirety

What is claimed is:

1. An impact sensor comprising at least one conductive polymer layer, a flexible substrate, and at least one electrode pair disposed between the at least one conductive polymer layer and the flexible substrate.

2. The impact sensor according to claim 1 wherein the flexible substrate comprises a polyimide membrane.

3. The impact sensor according to claim 1 wherein the conductive polymer layer is pressure sensitive and comprises a cross-linked synthetic polymer matrix and conductive nanoparticles.

4. The impact sensor according to claim 3 wherein the conductive nanoparticles are selected from the group consisting of silver, gold, copper, and an aqueous solution of Indium Tin Oxide (ITO) and a conductive polymer poly(3,4-ethylenedioxythiophene) poly(styrenesulfonate) (PEDOT:PSS).

5. The impact sensor according to claim 1 comprising a conductive electrode pair selected from the group consisting of aluminum, silver, gold, platinum, and copper electrodes.

6. The impact sensor according to claim 1 wherein the conductive polymer layer is encapsulated with SiNx.

7. The impact sensor according to claim 1 wherein the substrate has a thickness of about 20 microns to about 300 microns, a length of about 0.7 cm to about 2.54 cm , and a width of about 0.7 cm to about 2.54 cm.

8. The impact sensor according to claim 1 wherein each electrode has a length of about 0.7 cm to about 2.54 cm and a width of about 0.2 cm to about 0.5 cm.

9. The impact sensor according to claim 1 wherein the polymer layer has a thickness of about 0.5 mm to about 1.0 mm, a length of about 5.0 mm to about 1.5 cm, and a width of about 5.0 mm to about 1.0 cm.

10. The impact sensor according to claim 1 comprising a thickness of about 0.59 mm.

11. A method of making a flexible piezoresistive-based impact sensor comprising providing a flexible polyimide substrate, disposing an electrode pair on the substrate, and disposing on the electrodes a pressure-sensitive electrically conductive polymer composite layer comprising conductive nanoparticles.

12. The method according to claim 11 comprising disposing the electrode pair on the substrate by sputtering a highly conductive material thereon.

13. The method according to claim 11 wherein the conductive nanoparticles are selected from the group consisting of silver, gold, copper, and an aqueous solution of Indium Tin Oxide (ITO) and a conductive polymer poly(3,4-ethylenedioxythiophene) poly(styrenesulfonate) (PEDOT:PSS).

14. The method according to claim 11 wherein the electrode pair is selected from the group consisting of aluminum, silver, gold, platinum, and copper electrodes.

15. The method according to claim 11 comprising cleaning the substrate and modifying the substrate for better adhesion of deposited layers.

16. A combined temperature monitor and impact sensor comprising at least one conductive polymer layer, a flexible substrate, and at least one electrode pair disposed between the at least one conductive polymer layer and the flexible substrate.

17. The device according to claim 16 wherein the flexible substrate comprises a polyimide membrane.

18. The device according to claim 16 wherein the conductive polymer layer comprises a cross-linked polymer matrix and conductive nanoparticles.
